(19) United States
(12) Patent Application Publication
(10) Pub. No.: US 2026/0045920 A1
(43) Pub. Date: Feb. 12, 2026

(54) COMPOUND SEMICONDUCTOR AMPLIFIER AND CIRCUIT MODULE

(71) Applicant: Fujitsu Limited, Kawasaki-shi (JP)

(72) Inventors: NAOYA OKAMOTO, Isehara (JP); Shirou OZAKI, Yamato (JP); Yusuke KUMAZAKI, Atsugi (JP); YASUHIRO NAKASHA, Hadano (JP); Naoki HARA, Sagamihara (JP)

(73) Assignee: Fujitsu Limited, Kawasaki-shi (JP)

(21) Appl. No.: 19/340,499

(22) Filed: Sep. 25, 2025

Related U.S. Application Data
(63) Continuation of application No. PCT/JP2024/004611, filed on Feb. 9, 2024.

(30) Foreign Application Priority Data
Mar. 28, 2023 (JP) 2023-051136

(51) Int. Cl. H03F 3/193; H03F 1/30; H03F 3/195

(52) U.S. Cl. CPC H03F 3/1935; H03F 1/306; H03F 3/195

(57) ABSTRACT

A compound semiconductor amplifier includes, on an upper side of a semi-insulating substrate, a compound semiconductor, and an amplifier, wherein the semi-insulating substrate has a substrate thickness for converting a wavelength at a first frequency into a second range of wavelength inside the semi-insulating substrate, and includes, on a lower surface, a metal layer having a sheet resistance value in a third range, the first frequency is a maximum frequency being used in the compound semiconductor amplifier, the second range of wavelength is 1/12 to ½ of the wavelength of the first frequency, and the third range is 3 to 1000 ohms.

### CROSS-REFERENCE TO RELATED APPLICATION

This application is a continuation application under U.S.C. 111(a) of International Application No. PCT/JP2024/004611, filed on Feb. 9, 2024, now pending, which claims priority of Japanese Patent Application No. 2023-051136, filed on Mar. 28, 2023, the entire contents of each are incorporated herein by reference.

### FIELD

The present invention relates to a compound semiconductor amplifier and a circuit module.

### BACKGROUND

In next-generation communications (e.g. Beyond 5G/6G), the use of waves in sub-THz band has been studied in order to realize a communication speed of 100 Gbps or more. Accordingly, a compound semiconductor amplifier has attracted attention. The compound semiconductor amplifier as a sub-THz semiconductor amplifier is expected to be applied to the next generation communications because the compound semiconductor amplifier achieves higher frequency and higher power operation than a silicon-based amplifier.

Meanwhile, in order to stabilize high frequency and high output characteristics of a semiconductor amplifier (sub-THz semiconductor amplifier) used in the sub-THz band, it is important to suppress undesired electromagnetic wave radiation in a very wide frequency region, for example, 250 to 300 GHz. Furthermore, the sub-THz semiconductor amplifier has a power added efficiency of several %, and most of the input power is converted into heat, and the heat generation amount increases. In addition, in mobile communication, beam control of array antennas is desired. However, in this frequency region, the size of the sub-THz semiconductor amplifier exceeds the ½ wavelength (λ/2) of air (wavelength of a certain frequency in air), and thus a three-dimensional stacked antenna array structure has been proposed in which it is more difficult to form a heat dissipation structure (path) of the amplifier than a planar array antenna structure commonly used in a millimeter-wave band. For this reason, the heat dissipation structure of the sub-THz semiconductor amplifier is important.

Examples of the sub-THz semiconductor amplifier include a high-electron-mobility transistor (InP-based HEMT) in which an indium aluminum arsenide (InAlAs) electron supply layer and an indium gallium arsenide (InGaAs) channel layer are formed on an indium phosphide (InP) substrate, a HEMT (metamorphic HEMT, mHEMT) in which an InAlAs electron supply layer and an InGaAs channel layer are formed on a gallium arsenide (GaAs) substrate through a metamorphic buffer layer, and a heterojunction bipolar transistor (InP-based HBT) in which an InP emitter layer and a gallium arsenide antimony (GaAsSb) base layer and an In (Al) GaAs collector layer and the like are formed on an InP substrate. These compound semiconductor amplifiers achieve higher frequency and higher power operation than silicon-based amplifiers, and thus are expected for application to Beyond 5G/6G.

A technique related to the amplifier is described in Patent Literatures: JP 2007-165430 A; JP 2011-77557 A; and JP 2007-165739 A.

### SUMMARY

A compound semiconductor amplifier includes, on an upper side of a semi-insulating substrate, a compound semiconductor, and an amplifier, wherein the semi-insulating substrate has a substrate thickness for converting a wavelength at a first frequency into a second range of wavelength inside the semi-insulating substrate, and includes, on a lower surface, a metal layer having a sheet resistance value in a third range, the first frequency is a maximum frequency being used in the compound semiconductor amplifier, the second range of wavelength is 1/12 to ½ of the wavelength of the first frequency, and the third range is 3 to 1000 ohms.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a view illustrating an example of a cross-sectional view of a semiconductor amplifier 100.

FIG. 1B is a view illustrating an example of a top view of the semiconductor amplifier 100.

FIG. 2A is a diagram illustrating an example of a simulation result in a first embodiment.

FIG. 2B is a diagram illustrating an example of the simulation result in the first embodiment.

FIG. 2C is a diagram illustrating an example of the simulation result in the first embodiment.

FIG. 2D is a diagram illustrating an example of the simulation result in the first embodiment.

FIG. 3A is a view illustrating an example of a step of producing the semiconductor amplifier 100 according to the first embodiment.

FIG. 3B is a view illustrating an example of the step of producing the semiconductor amplifier 100 according to the first embodiment.

FIG. 3C is a view illustrating an example of the step of producing the semiconductor amplifier 100 according to the first embodiment.

FIG. 3D is a view illustrating an example of the step of producing the semiconductor amplifier 100 according to the first embodiment.

FIG. 4A is a view illustrating an example of a cross-sectional view of the semiconductor amplifier 100 according to the second embodiment.

FIG. 4B is a view illustrating an example of a top view of the semiconductor amplifier 100 according to the second embodiment.

FIG. 5A is a diagram illustrating an example of a simulation result in a second embodiment.

FIG. 5B is a diagram illustrating an example of the simulation result in the second embodiment.

FIG. 5C is a diagram illustrating an example of the simulation result in the second embodiment.

FIG. 5D is a diagram illustrating an example of the simulation result in the second embodiment.

FIG. 5E is a diagram illustrating an example of the simulation result in the second embodiment.

FIG. 5F is a diagram illustrating an example of the simulation result in the second embodiment.

FIG. 5G is a diagram illustrating an example of the simulation result in the second embodiment.

FIG. 5H is a diagram illustrating an example of the simulation result in the second embodiment.

FIG. 6A is a view illustrating an example of a step of producing the semiconductor amplifier 100 according to the second embodiment.

FIG. 6B is a view illustrating an example of the step of producing the semiconductor amplifier 100 according to the second embodiment.

FIG. 6C is a view illustrating an example of the step of producing the semiconductor amplifier 100 according to the second embodiment.

FIG. 6D is a view illustrating an example of the step of producing the semiconductor amplifier 100 according to the second embodiment.

FIG. 6E is a view illustrating an example of the step of producing the semiconductor amplifier 100 according to the second embodiment.

FIG. 6F is a view illustrating an example of the step of producing the semiconductor amplifier 100 according to the second embodiment.

FIG. 7 is a view illustrating an example of a conceptual diagram of a three-dimensional stacked structure of amplifier integrated array antennas.

FIG. 8 is a view illustrating an example of a circuit module in which a chip with a configuration according to the second embodiment is flip-chip mounted on a high-frequency circuit board.

FIG. 9 is a view illustrating an example of a circuit module in which a back surface of the chip with the configuration according to the second embodiment is mounted on a high-frequency circuit board.

FIG. 10 is a view illustrating an example of Table 1 showing characteristics of components used for substrates.

### DESCRIPTION OF EMBODIMENTS

Particularly in a frequency band of 250 GHz or more, there are two problems: transmission loss due to propagation of electromagnetic waves into semi-insulating substrates forming these compound semiconductor amplifiers and an increase in heat generation amount due to a significant decrease in power added efficiency. For these two problems, the thicknesses of the semi-insulating substrates forming the sub-THz compound semiconductor amplifiers are in a contradictory relationship, and it is difficult to solve the problems.

### First Embodiment

A first embodiment will be described.

### <Configuration Example of Semiconductor Amplifier>

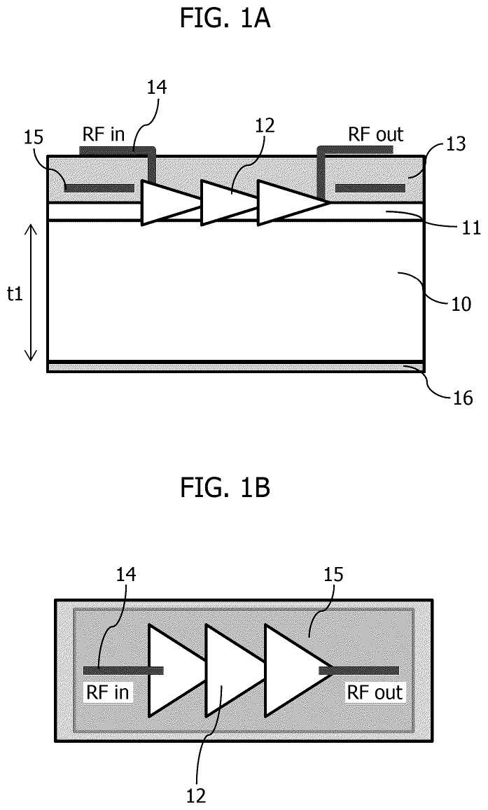

FIG. 1A is a view illustrating an example of a cross-sectional view of the semiconductor amplifier 100, and FIG. 1B is a view illustrating an example of a top view of the semiconductor amplifier 100.

The semiconductor amplifier 100 includes, for example, a semi-insulating substrate 10, a compound semiconductor epitaxial layer 11 grown on the semi-insulating substrate 10, an amplifier 12 produced on the compound semiconductor epitaxial layer 11, a wiring line layer including a microstrip wiring line 14 and a ground wiring line 15, each being formed on or in an interlayer insulating film 13 on the compound semiconductor epitaxial layer 11, and a metal layer 16. In the metal layer 16, a thin film having a sheet resistance of 6 to 1000Ω/□ is deposited on the back surface of the semi-insulating substrate 10 thinned to an extent of λ/4 to ½ of a predetermined maximum frequency. For example, in the case of an InP substrate or a GaAs substrate having a dielectric constant of about 12 at 300 GHz, the metal layer 16 has a substrate thickness of about 75 to 150 μm. Note that the predetermined maximum frequency is, for example, a maximum value of a frequency region of transmission radio waves in a case where the semiconductor amplifier 100 is used for an antenna. Also, the predetermined maximum frequency is, for example, a maximum value of a frequency region at the output (or input) of the semiconductor amplifier 100.

The effect of the configuration in which the metal layer 16 having a sheet resistance of 6 to 1000Ω/□ is disposed on the back surface of the semi-insulating substrate 10 on which the semiconductor amplifier 100 is formed will be described.

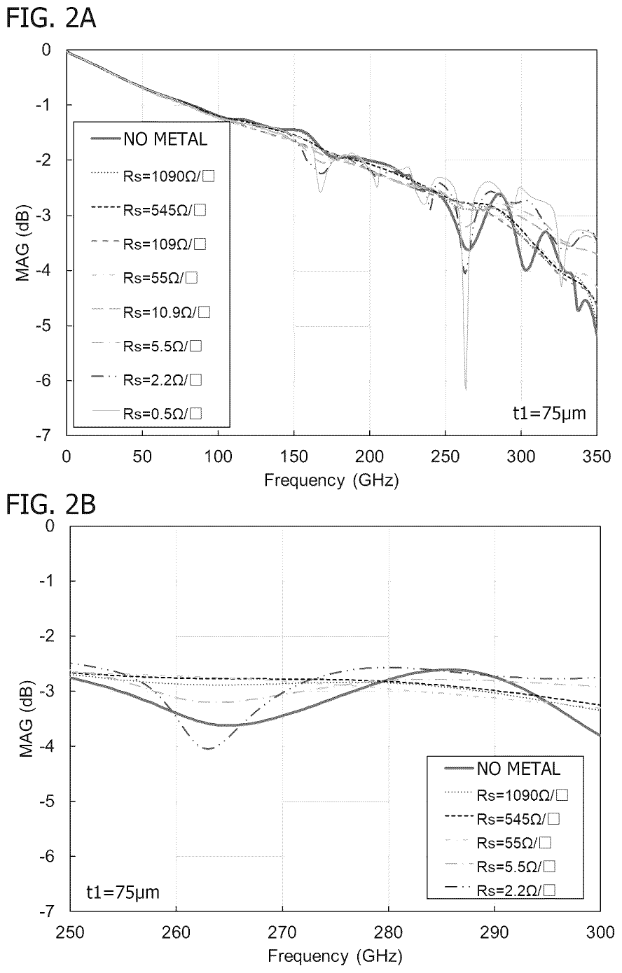

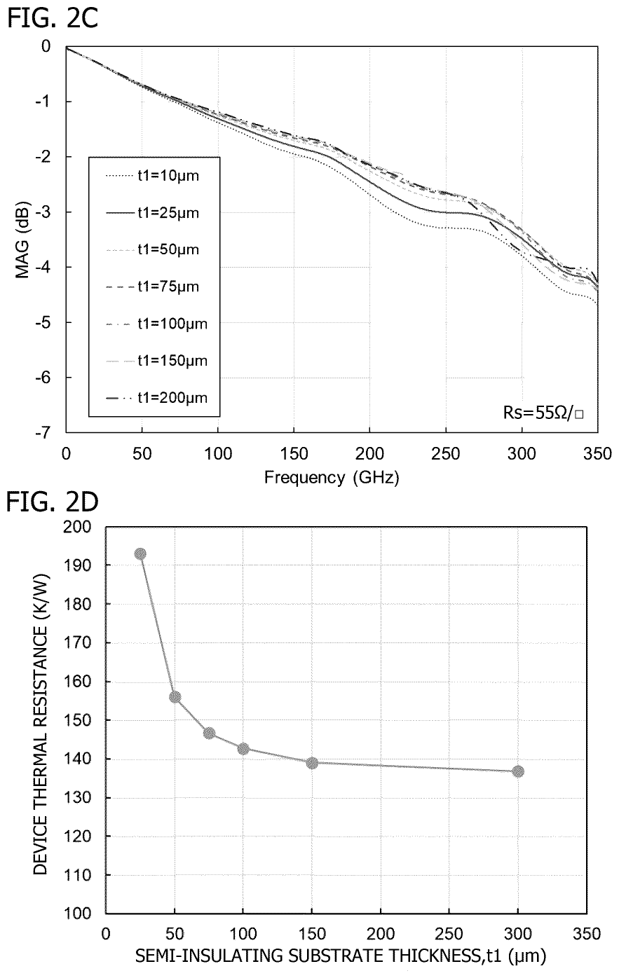

FIG. 2A is a diagram illustrating an example of a simulation result of a dependence property of transmission characteristics of the microstrip wiring line 14 formed on the semi-insulating substrate 10 having the metal layer 16 on the back surface of the substrate with respect to the sheet resistance of the metal layer 16.

The horizontal axis represents frequency, and the vertical axis represents maximum available gain (MAG). The semi-insulating substrate 10 is, for example, an InP substrate. A semi-insulating substrate thickness (t1) is, for example, 75 μm. When the metal layer 16 is not present on the back surface of the semi-insulating substrate, there is a frequency at which the MAG significantly decreases at 250 to 350 GHz. This is because propagation in the semi-insulating substrate 10 occurs in a specific frequency band and a transmission loss occurs.

FIG. 2B is a diagram illustrating an example of an enlarged view of FIG. 2A at 250 to 300 GHz. As illustrated in FIG. 2B, in a case where a sheet resistance (Rs) of the metal layer 16 disposed on the back surface of the semi-insulating substrate is in a range of 5.5 to 1090Ω/□, the transmission loss due to propagation in the substrate at around 260 GHz is suppressed as compared with a case where the metal layer 16 is not present. This is because when electromagnetic waves are applied to the metal layer 16 having a sheet resistance of about 6 to 1000Ω/□, a conductive current flows, the energy of the electromagnetic waves is converted into heat, the electromagnetic waves going around are absorbed without being reflected, and propagation of electromagnetic waves in the semi-insulating substrate is suppressed.

Meanwhile, when the sheet resistance of the metal layer 16 is smaller than 1Ω/□, for example, the metallic behavior becomes strong, and electromagnetic waves are reflected at the interface between the metal layer 16 and the semi-insulating substrate 10, which may enhance the loss due to the propagation of electromagnetic waves in the substrate. Accordingly, a preferred sheet resistance is, for example, 10.9 to 109 Ω/□.

FIG. 2C is a diagram illustrating an example of a simulation result of the dependence property of transmission characteristics of the microstrip wiring line 14 formed on the semi-insulating substrate 10 having the metal layer 16 on the back surface of the substrate with respect to the thickness of the semi-insulating substrate. The horizontal axis represents Frequency, and the vertical axis represents MAG. The semi-insulating substrate 10 is, for example, an InP substrate. The sheet resistance of the metal layer 16 is, for example, 55Ω/□. When the semi-insulating substrate thickness (t1) is in a range of 50 to 150 μm, loss due to propagation of electromagnetic waves in the substrate is suppressed, and there is almost no difference in transmission loss. However, when the thickness of the semi-insulating substrate is thinner than 25 μm or thicker than 150 μm, the loss at a band of 300 GHz increases. This is because, when the thickness is smaller than 25 μm, electromagnetic waves other than undesired emitted waves are absorbed by the metal layer 16. This is because, when the thickness is larger than 150 μm, the absorption of the undesired electromagnetic waves by the metal layer 16 is weakened.

Furthermore, FIG. 2D is a diagram illustrating an example of a simulation result of the dependence property of the device thermal resistance of the flip-chip mounted compound semiconductor amplifier 100 with respect to the thickness of the semi-insulating substrate. The heat source was set to 0.2 W, assuming that the sub-THz compound semiconductor amplifier had an output power of 10 mW and an efficiency of 4.8%. The semi-insulating substrate 10 is, for example, an InP substrate. In a known millimeter-wave band such as a band of 77 GHz used for a collision-avoidance radar of an automobile, λ/4 in the semi-insulating substrate is about 280 μm. In the frequency band, the device thermal resistance can be assumed to be substantially constant. However, in a case where the metal layer 16 is not used in the above-described sub-THz band, for example, 300 GHz, when the thickness of the substrate is reduced to about 25 μm capable of suppressing propagation of electromagnetic waves in the substrate, the device thermal resistance rapidly increases. This is because, when the thickness of the semi-insulating substrate 10 having a thermal conductivity of less than 100 W/mK becomes smaller than 75 μm, heat reaches the back surface of the substrate without sufficiently diffusing in the horizontal direction in the substrate, and thus the radiating area of the heat is small and the heat dissipation characteristics are deteriorated. However, the disposition of the metal layer 16 on the back surface of the substrate enables the thickness of the semi-insulating substrate to be increased to 150 μm. Thus, thermal diffusion in the semi-insulating substrate is promoted, and heat dissipation characteristics are improved.

As described above, in the configuration in which the metal layer 16 having a sheet resistance of 6 to 1000Ω/□ is disposed on the back surface of the semi-insulating substrate 10 on which the compound semiconductor amplifier is formed, the thickness of the semi-insulating substrate that achieves both suppression of propagation of electromagnetic waves and heat dissipation is 75 to 150 μm, which corresponds to an extent of λ/4 to λ/2 at a predetermined maximum frequency of 300 GHz.

### <Example of Step of Producing Semiconductor Amplifier>

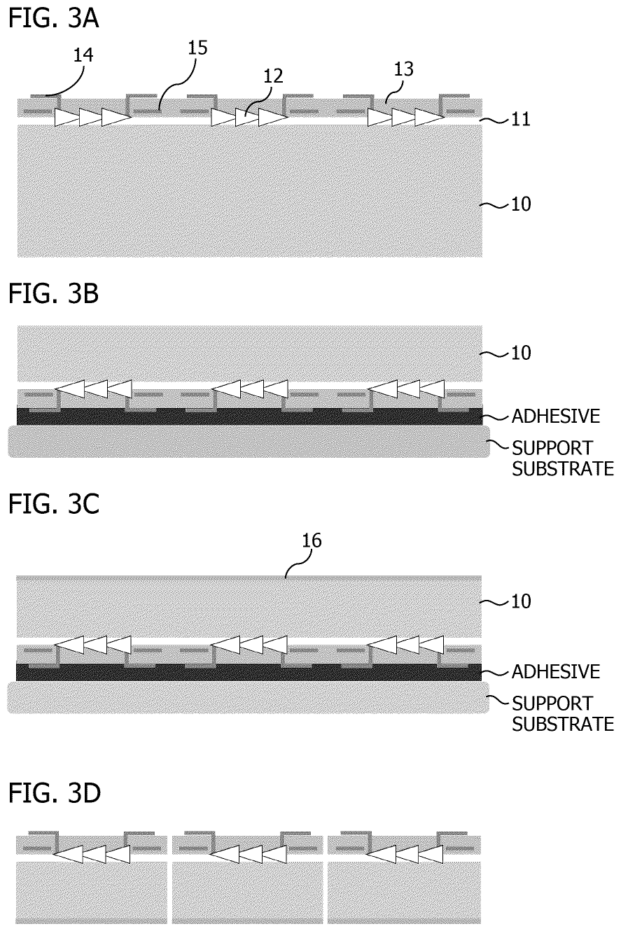

FIG. 3 is a view illustrating an example of a step of producing the semiconductor amplifier 100. First, as illustrated in FIG. 3A, a planarized wafer is produced using the compound semiconductor epitaxial layer 11 having an InP-based HEMT structure grown on an InP semi-insulating substrate and a thickness of about 0.5 μm, the amplifier 12 including a gate electrode, a source electrode, a drain electrode, a MIM capacitor, a NiCr resistance layer, and the like thereon, and a BCB interlayer insulating film having a ground-microstrip wiring line structure and a thickness of about 6 μm.

Next, as illustrated in FIG. 3B, an adhesive is applied to the surface of the wafer and attached to the support substrate, and then the back surface of the InP substrate is ground to make the thickness of the InP substrate 100 μm. The thickness of the substrate may be, for example, in a range of 75 to 150 μm. Chemical mechanical polishing (CMP) may or need not be performed. In the case of performing CMP, the thickness of the substrate after grinding is, for example, the sum of the final thickness of the substrate and the thickness of the film removed by CMP. Specifically, for example, in a case where a thickness of 10 μm is removed by CMP, when the thickness of the final substrate is 100 μm, the thickness of the substrate after grinding is 110 μm.

Next, as illustrated in FIG. 3C, titanium (Ti) of 13 nm is deposited on the back surface of the InP substrate by vacuum deposition or sputtering, for example. After the Ti layer is taken out from the vacuum apparatus, the Ti layer is naturally oxidized to an extent of about 3 nm, and thus the sheet resistance of the finished film is about 55 Ω/□.

Next, as illustrated in FIG. 3D, after the wafer is peeled off from the support substrate, the adhesive is removed with an organic solvent. Then, the back surface of the wafer is attached to a dicing tape and formed into chips by normal blade dicing.

Regarding the above example, although there has been described in the InP-based HEMT on the InP substrate, the InP-based HBT on the InP substrate or the mHEMT on the GaAs substrate may be used, or the GaN-based HEMT on gallium nitride (GaN), aluminum nitride (AlN), or SiC may be used. Therefore, GaAs, InP, GaN, AlN, or SiC can be used for the semi-insulating substrate 10.

Further, regarding the above example, although there has been described in the microstrip wiring line 14, a coplanar or grounded coplanar wiring structure may be used. As the interlayer insulating film 13, methyl silsesquioxane (MSQ) or polyimide can be used in addition to BCB.

As the metal layer 16, W, Mo, Ta, NiCr, Cr, Pt, Al, Au, Cu, Ag, or the like may be used, in addition to Ti in the above example. Further, a laminate of W, Mo, Ta, NiCr, Cr, Pt, Al, Au, Cu, or Ag may be used. The thickness of the metal layer 16 is preferably 6 nm or less for W, 20 nm or less for Ta, 3 nm or less for Au, 3 nm or less for Cu, 3 nm or less for Ag, 3 nm or less for Al, 20 nm or less for Cr, 20 nm or less for Pt, 10 nm or less for Mo, and 200 nm or less for NiCr. However, since a natural oxidation film (about several nm) is formed, the thickness of the film may be determined based on the sheet resistance of the finished film.

In the compound semiconductor amplifier 100 produced as described above, it is possible to obtain good heat dissipation characteristics while suppressing propagation of electromagnetic waves in the semi-insulating substrate.

### Second Embodiment

A second embodiment will be described.

### <Configuration Example of Semiconductor Amplifier>

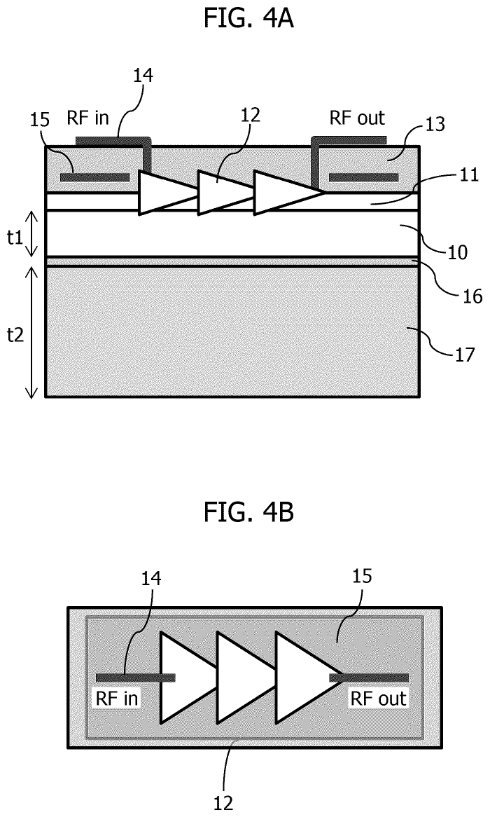

FIG. 4 are views illustrating examples of configurations of the semiconductor amplifier 100 in the second embodiment. FIG. 4A is a view illustrating an example of a cross-sectional view of the semiconductor amplifier 100, and FIG. 4B is a view illustrating an example of a top view of the semiconductor amplifier 100.

For example, the semiconductor amplifier 100 further includes a high heat dissipation substrate 17 as compared with the semiconductor amplifier 100 according to the first embodiment. In the semiconductor amplifier 100, the semi-insulating substrate 10 thinned to an extent of λ/12 to λ/2 of a predetermined maximum frequency and a high heat dissipation substrate having a thermal conductivity higher than a thermal conductivity of the semi-insulating substrate 10 and having an insulating property equal to or higher than an insulating property of the semi-insulating substrate 10 are bonded by the metal layer 16 having a sheet resistance of 3 to 1000 Ω/□.

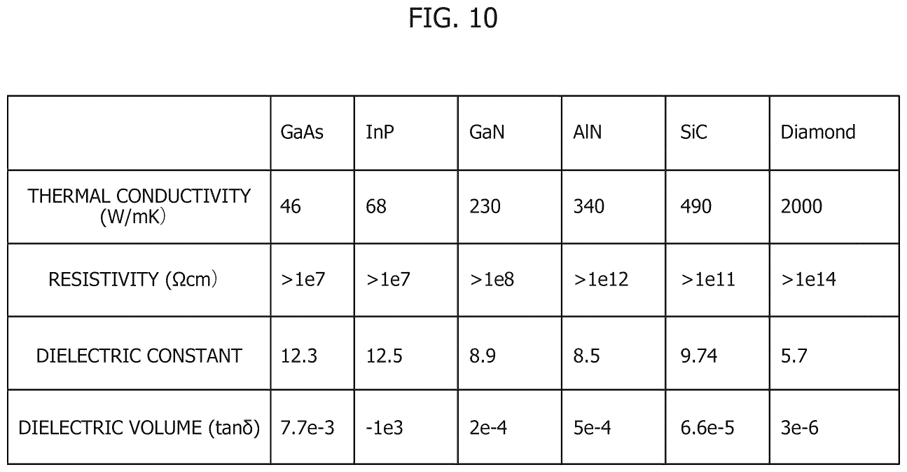

For example, in the case of an InP substrate or a GaAs substrate having a dielectric constant of about 12 at 300 GHz, the semi-insulating substrate 10 has a thickness of about 25 to 150 μm. As the high heat dissipation substrate, for example, a silicon carbide (SiC) substrate having a higher thermal conductivity, a higher resistivity (insulating property), and a smaller dielectric loss than the InP or GaAs substrate is used. The thickness of the substrate may be within 12 in the high heat dissipation substrate. For example, in the case of a SiC substrate having a dielectric constant of 9.74 at 300 GHz (see Table 1 in FIG. 10), the substrate thickness is set within about 300 μm. In addition, another high heat dissipation substrate may be, for example, gallium nitride (GaN), aluminum nitride (AlN), or diamond (see Table 1 in FIG. 10).

Next, in the compound semiconductor amplifier 100, the effect of the configuration in which the metal layer 16 having a sheet resistance of 3 to 1000Ω/□ is disposed at the bonding interface between the formed semi-insulating substrate 10 and the high heat dissipation substrate having a thermal conductivity higher than a thermal conductivity of the semi-insulating substrate 10 and an insulating property equal to or higher than an insulating property of the semi-insulating substrate 10 will be described.

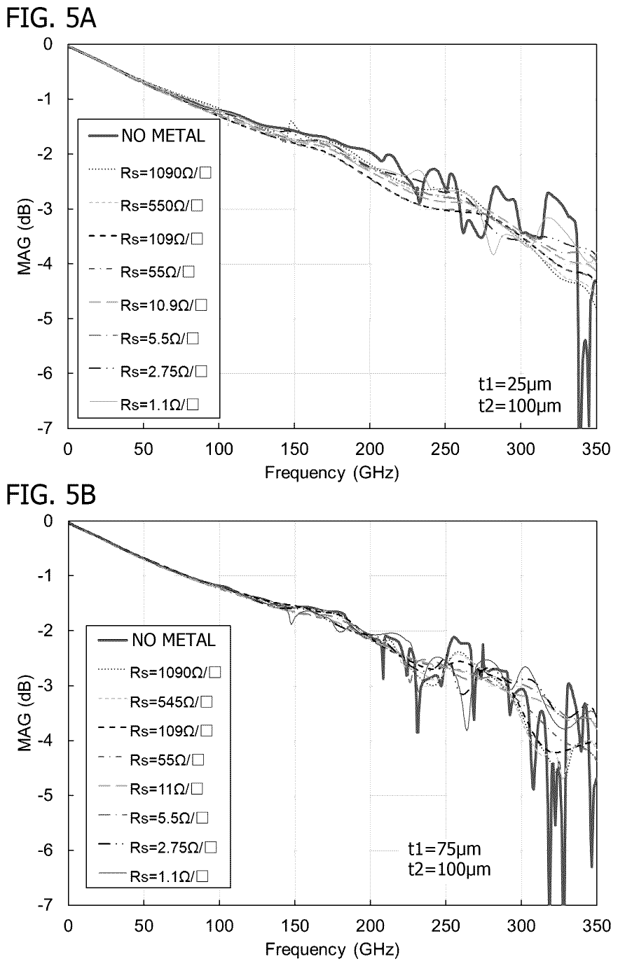

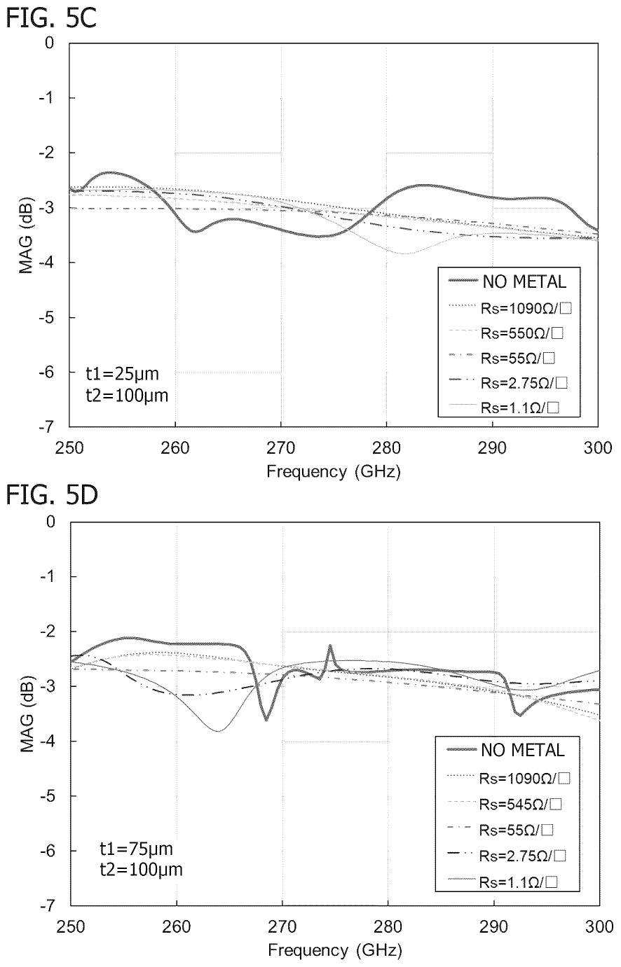

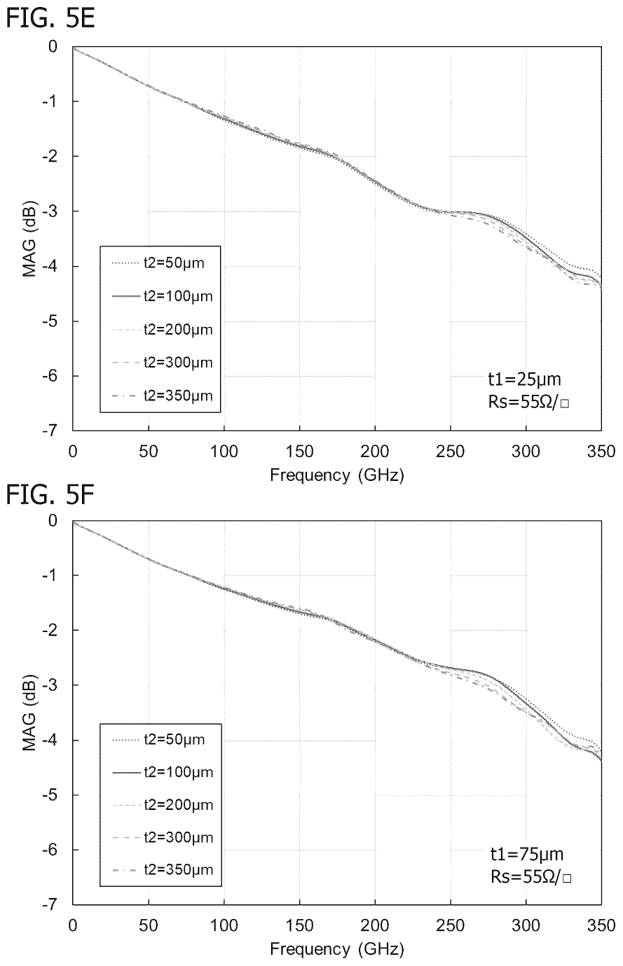

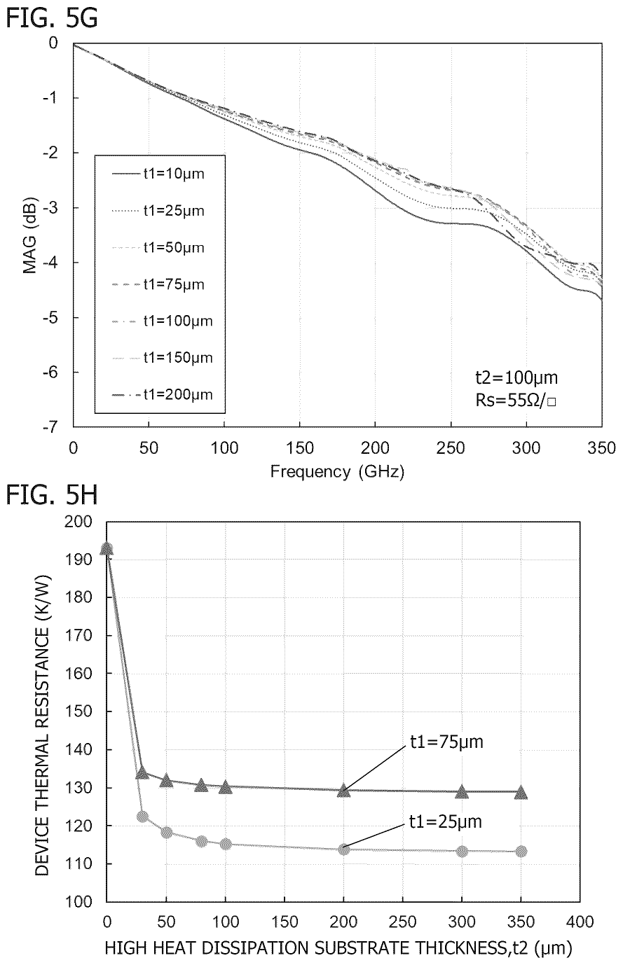

FIGS. 5A and 5B are diagrams illustrating examples of simulation results of the dependence property of transmission characteristics of the microstrip wiring line 14 formed on the semi-insulating substrate bonded to the high heat dissipation substrate through the metal layer 16 with respect to the sheet resistance of the metal layer 16. The horizontal axis represents Frequency, and the vertical axis represents MAG. The semi-insulating substrate 10 is, for example, an InP substrate, and the high heat dissipation substrate is, for example, a SiC substrate. The thicknesses (t1) of the semi-insulating substrate 10 are 25 μm (a) and 75 μm (b), respectively, and a high heat dissipation substrate thickness (t2) is 100 μm.

As illustrated in FIG. 5A, when the metal layer 16 is not present at the interface between the semi-insulating substrate 10 and the high heat dissipation substrate, there is a plurality of frequencies at which the MAG significantly decreases at 250 to 350 GHz. This is because propagation of electromagnetic waves in the semi-insulating substrate 10 and the high heat dissipation substrate occurs in a specific frequency band, and a transmission loss occurs.

FIGS. 5C and 5D are views illustrating examples of enlarged views of FIGS. 5A and 5B at 250 to 300 GHz, respectively. According to FIGS. 5A and 5B, when the sheet resistance (Rs) of the metal layer 16 at the interface between the semi-insulating substrate 10 and the high heat dissipation substrate is in a range of 2.75 to 1090Ω/□, the transmission loss due to propagation of electromagnetic waves in the substrate is suppressed even when the semi-insulating substrate thickness (t1) is 25 μm or 75 μm, as compared with a case where the metal layer 16 is not present. However, the sheet resistance of the metal layer 16 is about 1Ω/□, as a result of which the MAG decreases when the semi-insulating substrate thickness (t1) is 25 μm and the frequency is near 280 GHz and when the semi-insulating substrate thickness (t1) is 75 μm and the frequency is near 260 GHz. Thus, a preferred sheet resistance is, for example, 5.5 to 550Ω/□ for t1=25 μm and 11 to 55Ω/□ for t1=75 μm.

FIGS. 5E and 5F are diagrams illustrating examples of simulation results of the dependence property of transmission characteristics of the microstrip wiring line 14 formed on the semi-insulating substrate bonded to the high heat dissipation substrate through the metal layer 16 with respect to the thickness of the high heat dissipation substrate. The horizontal axis represents Frequency, and the vertical axis represents MAG. The semi-insulating substrate 10 is, for example, an InP substrate, and the high heat dissipation substrate is, for example, a SiC substrate. The semi-insulating substrate thickness (t1) is, for example, 25 μm (e) or 75 μm (f). The sheet resistance of the metal layer 16 is, for example, 55Ω/□. According to FIGS. 5E and 5F, it can be seen that when the high heat dissipation substrate thickness (t2) is in a range of 50 to 350 μm, the transmission loss due to propagation of electromagnetic waves in the substrate can be suppressed in both a case where the semi-insulating substrate thickness (t1) is 25 μm and a case where the semi-insulating substrate thickness (t1) is 75 μm.

FIG. 5G is a diagram illustrating an example of a simulation result of the dependence property of transmission characteristics of the microstrip wiring line 14 formed on the semi-insulating substrate bonded to the high heat dissipation substrate through the metal layer 16 with respect to the thickness of the semi-insulating substrate. The horizontal axis represents Frequency, and the vertical axis represents MAG. The semi-insulating substrate 10 is, for example, an InP substrate, and the high heat dissipation substrate is, for example, a SiC substrate. The high heat dissipation substrate thickness (t2) is, for example, 100 μm. The sheet resistance of the metal layer 16 is, for example, 55Ω/□. According to FIG. 5G, it can be seen that when the semi-insulating substrate thickness (t1) is in a range of 50 to 150 μm, loss due to propagation of electromagnetic waves in the substrate is suppressed, and there is almost no difference in transmission loss. However, it can be seen that when the semi-insulating substrate thickness is thinner than 25 μm or thicker than 150 μm, the transmission loss increases.

Further, FIG. 5H is a diagram illustrating an example of a simulation result of the dependence property of the device thermal resistance of the compound semiconductor amplifier 100 formed on the semi-insulating substrate bonded to the high heat dissipation substrate through the metal layer 16 with respect to the thickness of the high heat dissipation substrate. Similarly to the first embodiment, the flip-chip mounting is employed. In addition, the heat source was set to 0.2 W, assuming that the sub-THz compound semiconductor amplifier had an output power of 10 mW and an efficiency of 4.8%. The semi-insulating substrate 10 is, for example, an InP substrate, and the high heat dissipation substrate is, for example, a SiC substrate. The semi-insulating substrate thickness (t1) is, for example, 25 μm or 75 μm. In addition, it is assumed that surface activated bonding (SAB) or atomic diffusion bonding (ADB) is used for bonding, and the thermal resistance of the bonding interface is set to 5×10⁻⁸ m² K/W. Such bonding is performed in vacuum, and the bonded metal layer is not in direct contact with air. Consequently, it is possible to prevent oxidation and the like, and to contemplate the stabilization of the sheet resistance. According to FIG. 5H, it can be seen that the device thermal resistance rapidly decreases when the high heat dissipation substrate thickness (t2) is 30 μm or more. Meanwhile, it can be seen that the device thermal resistance when the semi-insulating substrate thickness (t1) is 25 μm is lower than the device thermal resistance when the semi-insulating substrate thickness (t1) is 75 μm, which is different from the tendency in the first embodiment. This is because heat is more rapidly transferred to the high heat dissipation substrate having a high thermal conductivity (490 W/mK) through the bonded metal layer as compared with a case where the heat is horizontally diffused in the semi-insulating substrate having a low thermal conductivity (68 W/mK), and heat is more efficiently dissipated in a case where the heat is horizontally diffused in the high heat dissipation substrate.

As described above, it is preferable that the thickness of the semi-insulating substrate that achieves both suppression of propagation of electromagnetic waves and heat dissipation is, for example, 25 to 150 μm, and corresponds to about λ/12 to λ/2 at a predetermined maximum frequency of 300 GHz. Also, it is preferable that the thickness of the high heat dissipation substrate is, for example, 50 to 350 μm, and corresponds to about λ/6 to 1λ at a predetermined maximum frequency of 300 GHz.

### <Example of Step of Producing Semiconductor Amplifier>

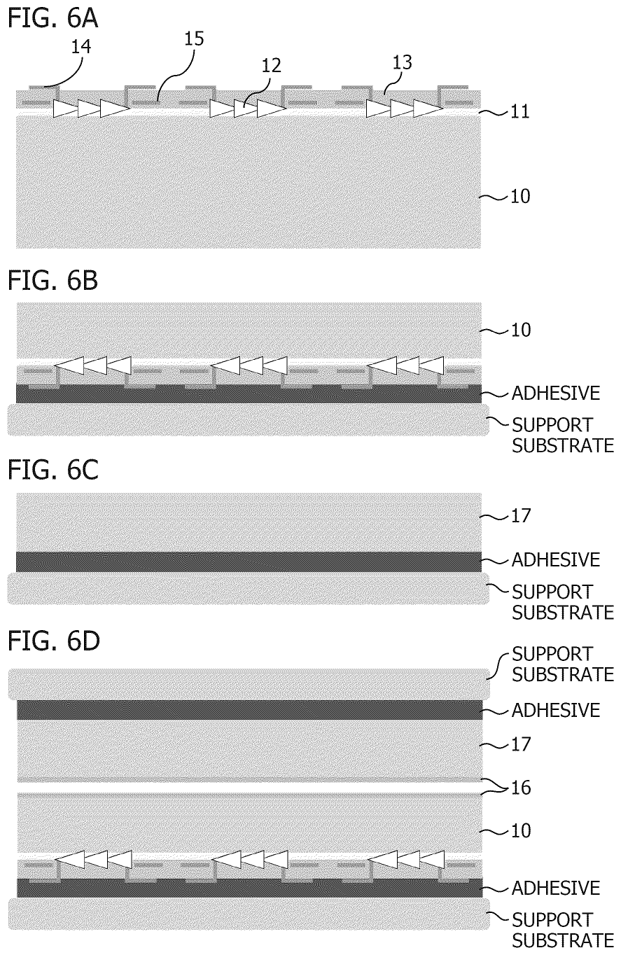

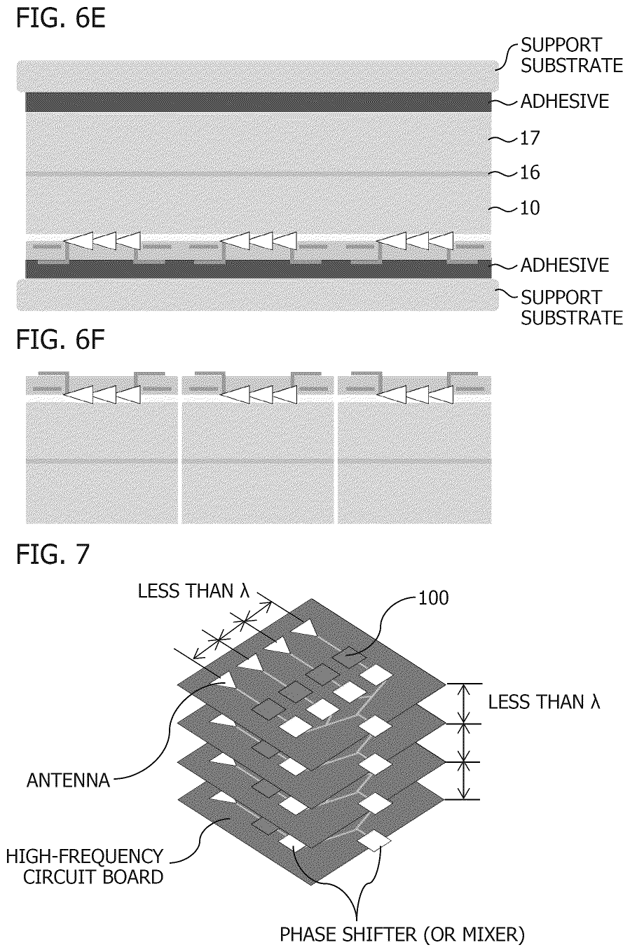

FIG. 6 illustrates views illustrating examples of the step of producing the semiconductor amplifier 100. The formation of the device on the front surface side in FIG. 6A is similar to that in FIG. 3A in the first embodiment.

Next, as illustrated in FIG. 6B, an adhesive is applied to the surface of the wafer and attached to the support substrate, and then the back surface of the InP substrate is ground to make the thickness of the InP substrate 85 μm. Further, a thickness of 10 μm is removed by CMP such that the InP substrate has a surface roughness (Ra) of less than 1 nm. As a result, the thickness of the final InP substrate becomes 75 μm. The thickness of the final InP substrate may be in a range of 25 to 150 μm.

Meanwhile, as illustrated in FIG. 6C, an adhesive is also applied to the surface of a wafer of a SiC substrate: a high heat dissipation substrate and attached to a support substrate, and then the SiC substrate is ground to make the thickness of the SiC substrate 100 μm. Further, CMP is performed such that the SiC substrate has a surface roughness (Ra) of less than 1 nm. Since the SiC substrate is a very hard material, it is hardly ground by CMP. As a result, the thickness of the final SiC substrate is also 100 μm.

In the SiC substrate, when the silicon (Si) surface side is a front side, the carbon (C) surface side is a back side, but either surface may be used. In addition, when the thickness of the final SiC substrate is about 300 μm, there is no need to perform the step of attaching to the support substrate. The thickness of the SiC substrate may be in a range of 50 to 350 μm.

Next, as illustrated in FIG. 6D, the two wafers are subjected to atomic diffusion bonding in a vacuum apparatus. First, Ti of 5 nm is deposited on the back surfaces of both the wafers at the same time. Thereafter, both the wafers are pressed at a predetermined pressure, and the Ti layers deposited on the back surfaces of both the wafers are bonded to each other. FIG. 6E is a diagram illustrating an example after joining.

In this case, a Ti layer having a thickness of 10 nm is formed at the bonding interface between the InP substrate and the SiC substrate, and the sheet resistance is 55Ω/□. The Ti layer present at the bonding interface may have a thickness of 100 nm or less.

Next, as illustrated in FIG. 6F, after the bonded wafer is peeled off from the support substrate, the adhesive is removed with an organic solvent. Thereafter, the back surface of the SiC substrate is attached to a dicing tape (not illustrated) and formed into chips by ultrasonic blade dicing.

Regarding the above example, although there has been described in the InP-based HBT on the InP substrate, the InP-based HEMT on the InP substrate or the mHEMT on the GaAs substrate may be used, or the GaN-based HEMT on the GaN, AlN, or SiC substrate may be used. When the GaAs or InP substrate is used as the semi-insulating substrate 10, GaN, AlN, SiC, or diamond can be used as the high heat dissipation substrate. When the GaN substrate is used as the semi-insulating substrate 10, the AlN, SiC, or diamond substrate can be used as the high heat dissipation substrate. When the AlN substrate is used as the semi-insulating substrate 10, the SiC or diamond substrate can be used as the high heat dissipation substrate. When the SiC substrate is used as the semi-insulating substrate 10, the diamond substrate can be used as the high heat dissipation substrate.

Further, regarding the above example, although there has been described using the microstrip wiring line 14, a coplanar or grounded coplanar wiring structure may be used. As the interlayer insulating film 13, methyl silsesquioxane (MSQ) or polyimide can be used in addition to BCB.

As the metal layer 16, W, Mo, Ta, NiCr, Cr, Pt, Al, Au, Cu, or Ag may be used as long as it is other than Ti. Further, a laminate of W, Mo, Ta, NiCr, Cr, Pt, Al, Au, Cu, or Ag may be used. In this case, the film thickness of the metal layer 16 after bonding is 6 nm or less for W, 20 nm or less for Ta, 3 nm or less for Au, 3 nm or less for Cu, 3 nm or less for Ag, 3 nm or less for Al, 20 nm or less for Cr, 20 nm or less for Pt, 10 nm or less for Mo, and 200 nm or less for NiCr.

In the above example, the atomic diffusion bonding technique is used for bonding, and it is also possible to deposit metal on the back surface of the wafer and then bond the wafer using the surface activated bonding technique.

In the semiconductor amplifier 100 produced as described above, it is possible to stabilize heat dissipation characteristics and sheet resistance of the metal layer 16 while suppressing propagation of electromagnetic waves in the semi-insulating substrate 10 and the high heat dissipation substrate.

### Third Embodiment

A third embodiment will be described. In the third embodiment, an example of a circuit module applied to a three-dimensional stacked structure of amplifier integrated array antennas will be described.

FIG. 7 is a view illustrating an example of a conceptual diagram of a three-dimensional stacked structure of amplifier integrated array antennas. The structure is such that four 1×4 amplifier integrated array antennas, each of which has an antenna, the compound semiconductor amplifier 100, a phase shifter, or a mixer disposed on one high-frequency circuit board, are stacked in a vertical direction. In this case, in order to suppress undesired grating lobe, at least the interval of the antenna is set to be less than one wavelength (λ) of air in the horizontal and vertical directions. The interval is preferably set to a wavelength of λ/2. That is, it is important to control the thickness in the vertical direction.

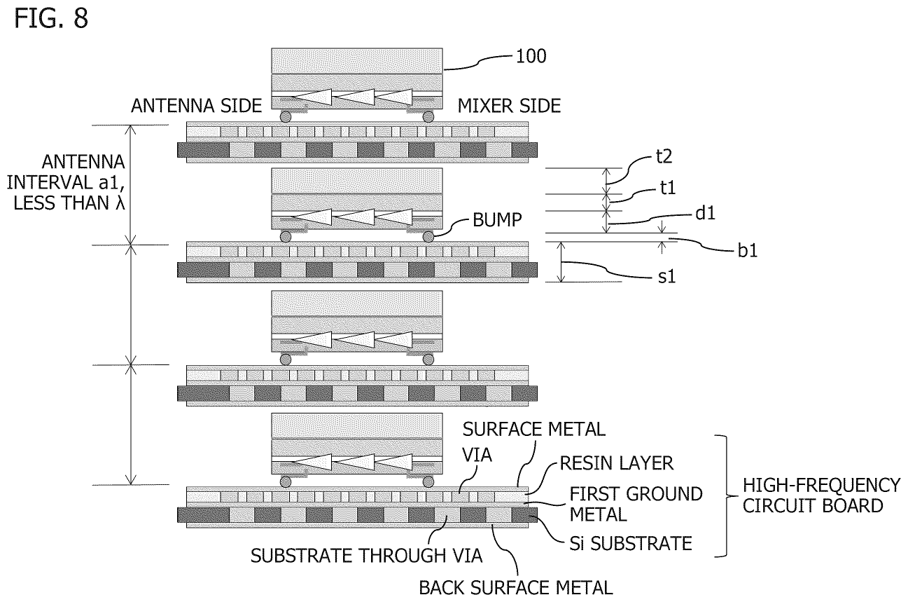

FIG. 8 is a view illustrating an example of a circuit module in which a chip with a configuration according to the second embodiment is flip-chip mounted on a high-frequency circuit board. As the high-frequency circuit board, for example, a high-frequency circuit board including: a Si substrate, a back surface metal formed on a back surface of the Si substrate; a first ground metal connected to the back surface metal through a substrate through via penetrating the Si substrate; a resin layer such as polyimide formed on the first ground metal; and a surface metal connected to the first ground metal through a via penetrating the resin layer (prior application (application number: 2022-056168)) is used.

In addition, the high-frequency circuit board is supported by silicon interposers or columns (not illustrated) made of metal on the upper and lower sides. In this case, a high-frequency circuit board thickness (s1) is 245 μm. Further, a bump height (b1) is 15 μm. A device layer thickness (d1) is 10 μm in the case of the InP-based HEMT. An antenna interval (a1) is 1 mm (1000 μm) in the case of 1λ at a predetermined maximum frequency of 300 GHz, and the difference is 730 μm. The film thickness of the metal layer 16 can be ignored because it is less than 0.2 μm at the maximum. The sum of a SiC substrate thickness (t2) and an InP substrate thickness (t1) according to the second embodiment is 500 μm at the maximum. Meanwhile, when the antenna interval (a1) is λ/2 (500 μm), the difference is 230 μm. When the sum of the SiC substrate thickness (t2) and the InP substrate thickness (t1) according to the second embodiment is less than 230 μm, mounting is possible. For example, even when the thickness of the InP substrate is 75 μm, the SiC substrate thickness can be used up to 150 μm. In addition, a thermal interface material (TIM) may be interposed between the back surface of the chip of the amplifier 12 flip-chip mounted on the high-frequency circuit board and the high-frequency circuit board on the upper part of the back surface. In addition, since the substrate thickness of the chip having the configuration according to the first embodiment is 150 μm at the maximum, the chip can be easily mounted.

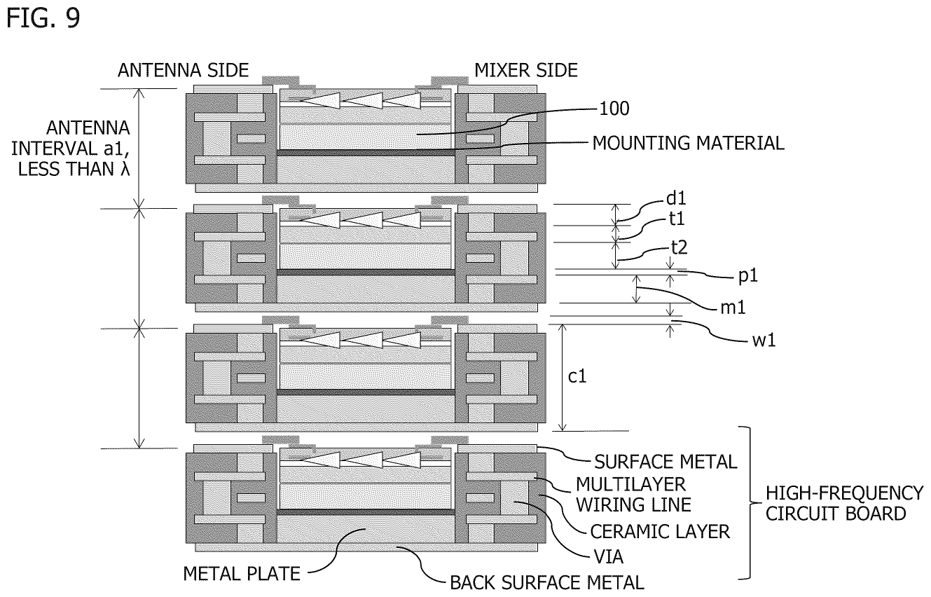

FIG. 9 is a view illustrating an example of a circuit module in which a back surface of the chip with the configuration according to the second embodiment is mounted on a high-frequency circuit board. A general low temperature co-fired ceramics (LTCC) substrate is used as the high-frequency circuit board. Further, the high-frequency circuit board is supported by metal columns (not illustrated) on the upper and lower sides. The high-frequency circuit board has a configuration in which a multilayer wiring line embedded in a ceramic layer, a surface metal (ground only) connected to a back surface metal through a via, and a metal plate for heat dissipation are embedded at a position where the surface metal and the surface of a compound semiconductor amplifier chip are flush with each other (a portion of a mounting material is subtracted). The metal plate is copper (Cu). When the surface metal of the high-frequency circuit board, the microstrip of the compound semiconductor amplifier 100, and the ground wiring line are connected by wire bonding, a wiring height (w1) is about 90 μm in loop height. Assuming that the antenna interval (a1) is 12 (1 mm) at a predetermined maximum frequency of 300 GHz, the difference is 910 μm. In order to prevent the contact of the upper high-frequency circuit board with the back surface metal, a high-frequency circuit board thickness (c1) is set to 900 μm in consideration of a 10 μm margin. The device layer thickness (d1) is 10 μm in the case of the InP-based HEMT. When the amplifier chip is mounted on the metal plate with a Ag paste, a mounting thickness (p1) is 25 μm. Since the sum of the SiC substrate thickness (t2) and the InP substrate thickness (t1) according to the second embodiment is 500 μm at the maximum, a metal plate thickness (m1) is 415 μm and functions appropriately as a heatsink. Meanwhile, when the antenna interval (a1) is λ/2 (500 μm), the high-frequency circuit board thickness (c1) is 400 μm. In this case, when the metal plate thickness (m1) is half of the value: 200 μm, the difference is 200 μm. When the sum of the SiC substrate thickness (t2) and the InP substrate thickness (t1) according to the second embodiment is a value (less than 165 μm) obtained by subtracting the mounting thickness (p1): 25 μm and the device layer thickness (d1): 10 μm, mounting is possible. For example, even when the SiC substrate thickness is 100 μm, the InP substrate thickness can be used up to 65 μm.

As described above, in the circuit module according to the third embodiment, since the high-frequency circuit boards on which the semiconductor amplifiers having the configurations according to the first embodiment and the second embodiment are mounted can be stacked in a vertical direction at an interval of λ/2 to λ of air, it is possible to perform beam control with grating lobe suppression in the array antenna to which the circuit module is applied.

In the third embodiment, a transmission/reception device is equipped with the array antenna to which the circuit module is applied, as a result of which it is possible to provide, for example, a communication system device for Beyond 5G/6G.

### OTHER EMBODIMENTS

The embodiments may be used in combination. For example, the circuit module according to the third embodiment may have both the semiconductor amplifier 100 according to the first embodiment and the semiconductor amplifier 100 according to the second embodiment depending on the cost and the intended use.

In addition, the components in each of the embodiments are not limited to the substances described in the examples. For example, the components may be capable of being replaced with other substances having similar actions, effects, or characteristics.

According to one disclosure, it is possible to suppress the heat generation amount while suppressing propagation of electromagnetic waves.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor amplifier comprising: on an upper side of a semi-insulating substrate,
a compound semiconductor; and an amplifier,
wherein the semi-insulating substrate has a substrate thickness for converting a wavelength at a first frequency into a second range of wavelength inside the semi-insulating substrate, and includes, on a lower surface, a metal layer having a sheet resistance value in a third range,
the first frequency is a maximum frequency being used in the compound semiconductor amplifier,
the second range of wavelength is 1/12 to ½ of the wavelength of the first frequency, and
the third range is 3 to 1000 ohms.

2. The compound semiconductor amplifier according to claim 1, wherein the second range of wavelength is ¼ to ½ of the wavelength of the first frequency, and
the third range is 6 to 1000 ohms.

3. The compound semiconductor amplifier according to claim 1, wherein the metal layer includes a high heat dissipation substrate on a side opposite to the semi-insulating substrate, and
the high heat dissipation substrate has a thermal conductivity higher than a thermal conductivity of the semi-insulating substrate and a resistivity equal to or higher than a resistivity of the semi-insulating substrate.

4. The compound semiconductor amplifier according to claim 1, wherein a component of the semi-insulating substrate includes gallium arsenide, indium phosphide, gallium nitride, aluminum nitride, or silicon carbide.

5. The compound semiconductor amplifier according to claim 3, wherein a component of the high heat dissipation substrate includes gallium nitride, aluminum nitride, silicon carbide, or diamond.

6. The compound semiconductor amplifier according to claim 3, wherein the high heat dissipation substrate has a substrate thickness that is ⅙ to 1 of the wavelength of the first frequency inside the high heat dissipation substrate.

7. The compound semiconductor amplifier according to claim 1, wherein a component of the metal layer includes titanium, tungsten, molybdenum, tantalum, nichrome, chromium, platinum, aluminum, gold, copper, silver, or a laminate of titanium, tungsten, molybdenum, tantalum, nichrome, chromium, platinum, aluminum, gold, copper, or silver.

8. A circuit module that stacks a high-frequency circuit board on which a compound semiconductor amplifier is mounted at an interval of ½ to one wavelength at a first frequency with respect to a wavelength in air,
the compound semiconductor amplifier including: on an upper side of a semi-insulating substrate,
a compound semiconductor; and an amplifier,
wherein the semi-insulating substrate has a thickness for converting a wavelength at a first frequency into a second range of wavelength inside the semi-insulating substrate, and includes, on a lower surface, a metal layer having a sheet resistance value in a third range,
the first frequency is a maximum frequency being used in the compound semiconductor amplifier,
the second range of wavelength is 1/12 to ½ of the wavelength of the first frequency, and
the third range is 3 to 1000 ohms.

9. The circuit module according to claim 8, wherein the metal layer includes a high heat dissipation substrate on a side opposite to the semi-insulating substrate,
the high heat dissipation substrate has a thermal conductivity higher than a thermal conductivity of the semi-insulating substrate and a resistivity equal to or higher than a resistivity of the semi-insulating substrate, and
a sum of a thickness of the semi-insulating substrate and a thickness of the high heat dissipation substrate falls within a fourth range.

10. The circuit module according to claim 9, wherein the fourth range is 75 to 500 micrometers.

11. The circuit module according to claim 8, wherein a component of the semi-insulating substrate includes gallium arsenide, indium phosphide, gallium nitride, aluminum nitride, or silicon carbide.

12. The circuit module according to claim 9, wherein a component of the high heat dissipation substrate includes gallium nitride, aluminum nitride, silicon carbide, or diamond.

13. The circuit module according to claim 9, wherein the high heat dissipation substrate has a substrate thickness that is ⅙ to 1 of the wavelength of the first frequency inside the high heat dissipation substrate.

14. The circuit module according to claim 8, wherein a component of the metal layer includes titanium, tungsten, molybdenum, tantalum, nichrome, chromium, platinum, aluminum, gold, copper, silver, or a laminate of titanium, tungsten, molybdenum, tantalum, nichrome, chromium, platinum, aluminum, gold, copper, or silver.
